(19) United States
(12) Patent Application Publication
(10) Pub. No.: US 2006/0232948 A1
(43) Pub. Date: Oct. 19, 2006

(54) Case for stackable PCBs

(76) Inventors: James A. Haager, Phoenix, AZ (US); Ronald E. Tupa, Mesa, AZ (US); Daniel P. Fogelson, Chandler, AZ (US)

Correspondence Address: C. ROBERT VON HELLENS;CAHILL, VON HELLENS & GLAZER P.L.C., 155 PARK ONE,, 2141 E. HIGHLAND AVENUE, PHOENIX, AZ, 85016, US

(21) Appl. No.: 11/106,978

(22) Filed: Apr. 15, 2005

(51) Int. Cl. H05K 7/14

(52) U.S. Cl. 361/752; 361/758; 361/759

(57) ABSTRACT

A case adapted for housing and protecting one or more stacked printed circuit boards and conforming with an industry small form factor specification. For a single printed circuit board, a cover includes sidewalls for encircling the printed circuit board and supports for attaching the printed circuit board thereto. The cover is keyed to and attached to a support element that may enclose the circuit board therewithin. One or more openings in the case provide access to external electrical connectors. For stacked printed circuit boards, a spacer supports a pair of printed circuit boards. A cover extends across the top of the spacer to enclose the printed circuit boards and screws extend through the cover into the spacer to secure these elements with one another. For additional printed circuit boards, further spacers, each supporting a printed circuit board are stacked between the first spacer and the cover.

### BACKGROUND OF THE INVENTION

1. Field of the Invention

The present invention relates to modular units for enclosing printed circuit boards, and, more particularly, to a case for enclosing stacked printed circuit boards.

2. Description of Related Prior Art

In the field of electronic equipment of various types, certain industry standards have been developed by the Electronic Industries Association (EIA) for the width and length of modular units housing various electronic equipment. Such standards may be referred to as form factor. In particular, these are EIA Specifications for Small Form Factor 63.5 mm (2.5″) disk drives and for Small Form Factor 88.9 mm (3.5″) disk drives.

Printed circuit boards (hereinafter “PCBs”) are relatively densely populated with the relevant components but they are relatively fragile and may be damaged by rough handling during installation and replacement. Moreover, two or more PCBs may be required to satisfy the function and operation of an electric signal circuit of a particular electronic equipment. Furthermore, multiple PCBs may be used to obtain redundancy and the benefits resulting therefrom.

When the single PCB or multiple PCBs are electrically interconnected to perform a specific function, many benefits are achieved by housing such a single PCB or multiple PCBs within a protective case. Such a case would expose the pins of one or more electrical connectors for electrical connection with ancillary circuitry and the like.

### SUMMARY OF THE INVENTION

A cover, which forms a case for a single printed circuit board (PCB) has at least one partly cutaway sidewall and the PCB includes one or more electrical connectors having pins accessible through the cutaway sidewall. The cover includes standard sized threaded apertures for attachment of the case to a support element. To house more than one PCB within the case, a spacer coincident with the boundary of the case, supports one or more PCBs. Depending upon the depth of the spacer and the height of the components mounted on the PCBs, the cover may be a flat plate secured to the spacer. To add further PCBs, additional spacers may be interconnected to support the added PCBs.

Interconnection between two or more PCBs is provided by a pair of male/female electrical connectors disposed intermediate adjacent PCBs that are mechanically and electrically interconnected upon mounting of each additional PCB. The length and width of the case, irrespective of the number of stacked PCBs, conforms with an industry standard small form factor.

It is therefore a primary object of the present invention to provide a case for one or any number of stacked PCBs.

Another object of the present invention is to provide a case for stacked PCBs that conforms with an industry standard small form factor specifications.

Yet another object of the present invention is to provide spacers for supporting one or more PCBs of a stack of PCBs disposed beneath a cover.

Still another object of the present invention is to provide a case for stacking PCBs having spacers for supporting additional PCB and of a height commensurate with the components mounted on the respective PCB.

A further object of the present invention is to provide an industry standard case attachable to a support element for housing one or more stacked PCBs.

A yet further object of the present invention is to provide a method for mounting electrically interconnected PCBs within a case.

A still further object of the present invention is to provide a method for housing one or any number of stacked PCBs within a case of specified dimensions.

These and other objects of the present invention will become apparent to those skilled in the art as the description thereof proceeds.

### BRIEF DESCRIPTION OF THE DRAWINGS

The present invention will be described with greater specificity and clarity with reference to the following drawings, in which:

FIG. 1 illustrates a cover for supporting a printed circuit board;

FIG. 2 illustrates a top view of the cover shown in FIG. 1;

FIG. 3 is a top view of a printed circuit board located within the cover shown in FIG. 1;

FIG. 4 is a side view taken along lines 4-4, as shown in FIG. 3;

FIG. 5 is a top view of the case;

FIG. 6 is an end view taken along lines 6-6, as shown in FIG. 5;

FIG. 7 is an exploded view illustrating two stacked printed circuit boards, a spacer and a flat cover;

FIG. 8 illustrates a top isometric view of the assembly as shown in FIG. 7;

FIG. 9 is an end view taken along lines 9-9, as shown in FIG. 8;

FIG. 10 is an exploded view showing three stacked printed circuit boards, two spacers and a flat cover;

FIG. 11 is a top isometric view of the assembly shown in FIG. 10;

FIG. 12 is an end view taken along lines 12-12, as shown in FIG. 11;

FIG. 13 is an exploded view illustrating four printed circuit boards, three spacers and a flat cover;

FIG. 14 is a top isometric view of the assembly shown in FIG. 13;

FIG. 15 is an end view taken along lines 15-15, as shown in FIG. 14; and

FIG. 16 is a representative underside exploded view of several printed circuit boards and spacers.

### DESCRIPTION OF THE PREFERRED EMBODIMENT

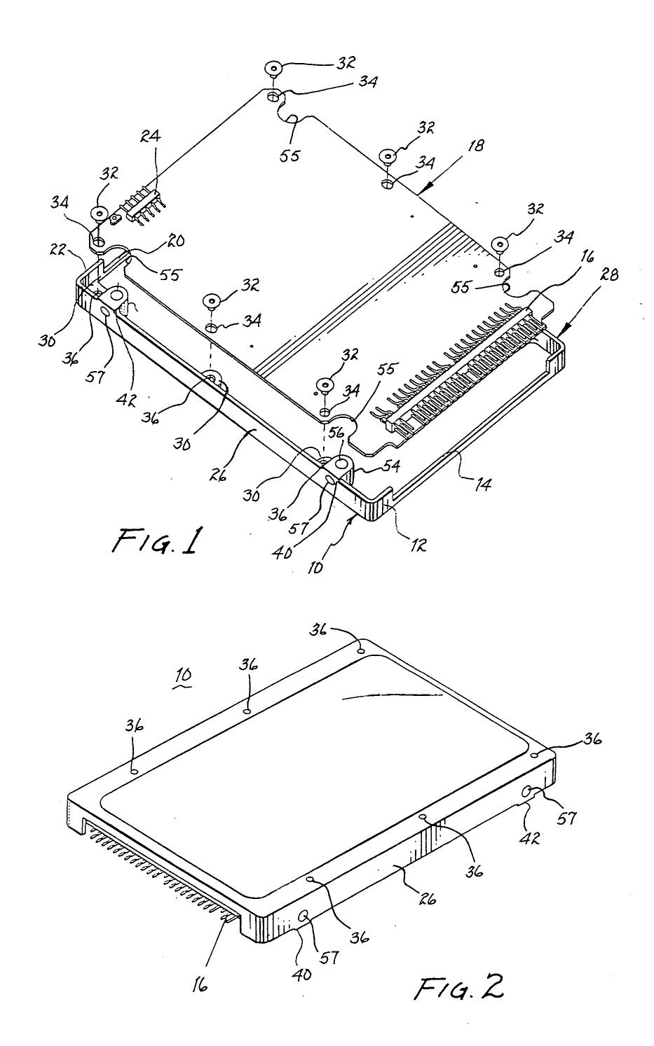

Referring to FIGS. 1 and 2, there is shown a cover 10 conforming with an industry small form factor specification (EIA specification). Sidewall 12 at one end includes an indentation 14 for providing access to a male electrical connector 16 mounted at the end of printed circuit board (PCB) 18. A further indentation 20 may be located in end wall 22 to provide access to a male electrical connector 24 mounted on PCB 18. As illustrated, three supports 30 are disposed adjacent the interior surface of sidewall 26. Similar supports (not shown) are disposed adjacent the interior surface of sidewall 28. PCB 18 is firmly attached to cover 10 by screws 32 penetrating corresponding apertures 34 in the PCB for threaded engagement with threaded apertures 36 respective supports 30. A pair of bosses 54 may be disposed adjacent each sidewall 26, 28. The bosses include threaded passageways 56 for engagement with screws to secure cover 10 to a support element.

Cover 10 may be attached to a support element by screws engaging the lower part of threaded passageways 56 in bosses 54. The cover further includes threaded passageways 57 in sidewalls 26, 28 for use in attaching cover 10 to a support element. Both of these modes of attachment are in accordance with the industry small form factor specification. Moreover, keys 40, 42 extend from sidewall 26 and similar keys, of which key 44 is shown in FIG. 6, extend from sidewall 28.

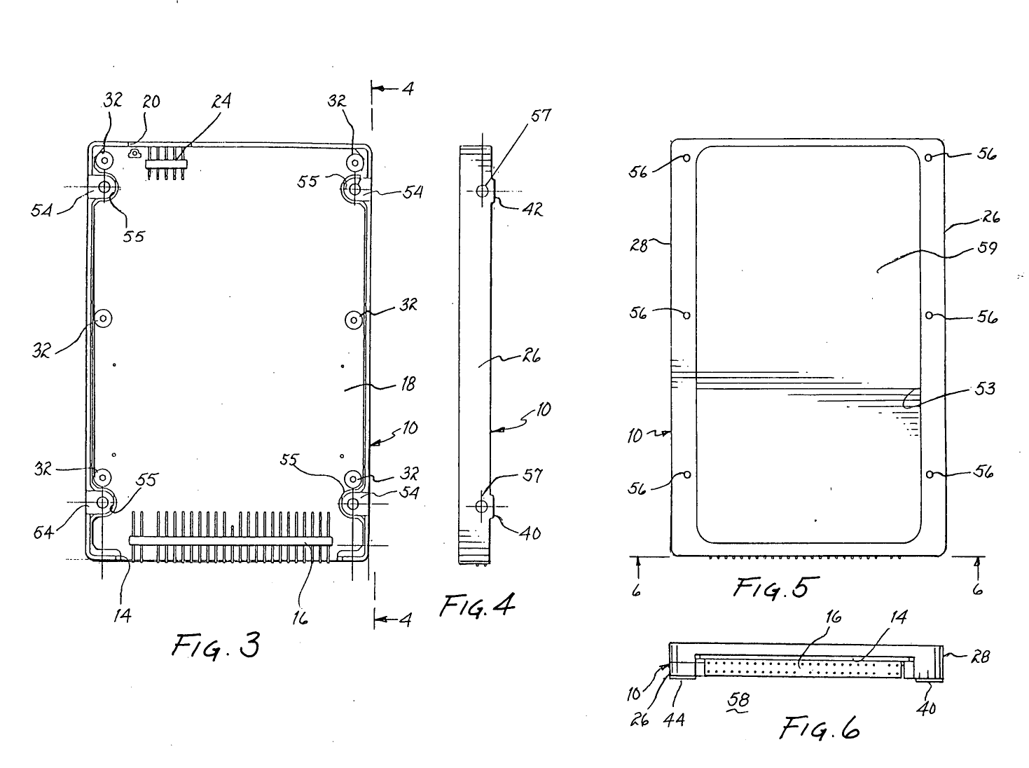

Referring jointly to FIGS. 3, 4, 5 and 6, various views of PCB 18 attached to cover 10 are illustrated. In particular, FIG. 3 illustrates PCB 18 secured within cover 10 by a plurality of screws 32. A plurality of recesses 55 are formed in PCB 18 to accommodate insertion of respective ones of bosses 54. Additionally, access to electrical connectors 16 and 24 is through indentations 14, 20, respectively, as shown. FIG. 5 shows a top view of the assembly, which assembly conforms with the dimensions of an industry small form factor specification. As represented by rectangular line 53, a label 59 or the like may be attached to the top surface of cover 10. FIG. 6 particularly illustrates case 58 formed by cover 10 containing PCB 18. Access to electrical connector 16 is through indentation 14 in the cover.

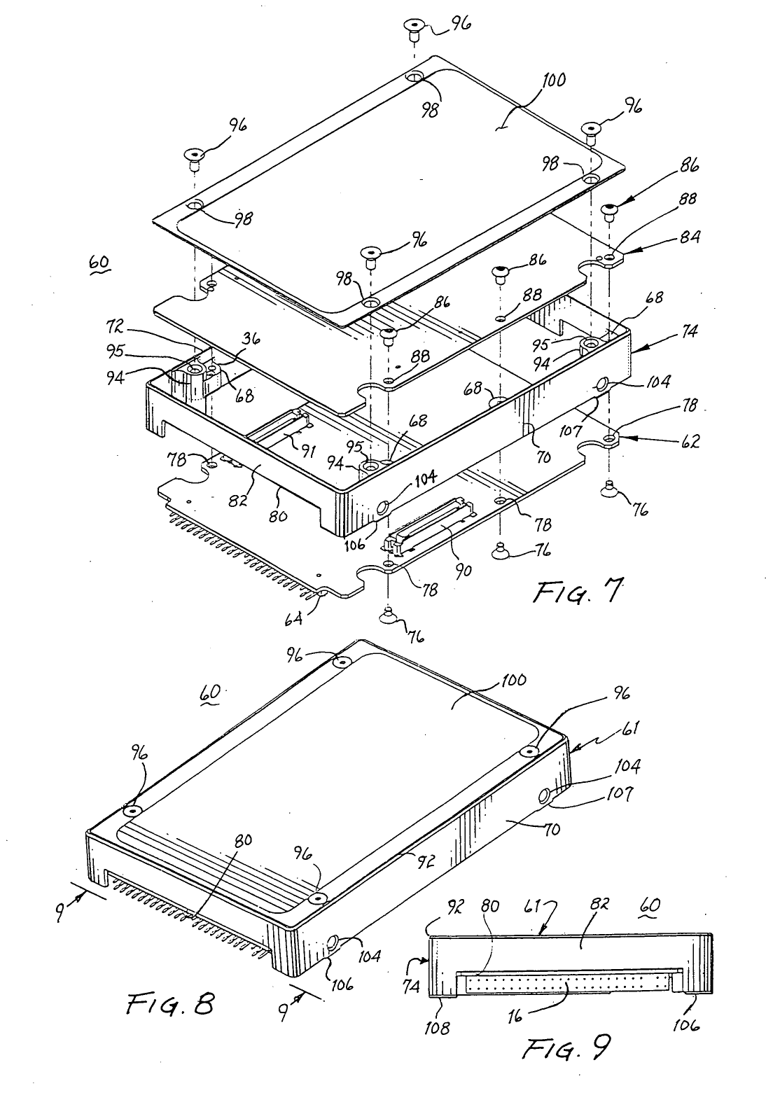

Referring jointly to FIGS. 7, 8 and 9, there is shown a first variant 60 of a case 61 for supporting stacked PCBs. A printed circuit board (PCB) 62 includes an electrical connector 64 attached to the underside thereof for mating engagement with a corresponding electrical connector external to the case. PCB 62 is secured to apertures 36 in the underside of supports 68 disposed along the interior surface of sidewalls 70, 72 of a spacer 74 by screws 76 penetrably engaging apertures 78 in the PCB. Upon such placement, the pins of electrical conductor 64 become located within indentation 80 in wall 82 of spacer 74. A further PCB 84 rests upon each of supports 68 and is secured thereto by a plurality of screws 86 penetrably engaging apertures 88 in the PCB. Upon attachment of PCBs 62, 84 to spacer 74, electrical connectors 90, 91 mounted on PCB 62 mechanically and electrically engage corresponding electrical connectors dependingly supported from PCB 84 (see FIG. 16). To secure flat cover 92, screws 96 penetrably engage apertures 98 in the cover and extend into threaded passageways 95 in bosses 94. A label 100 may be attached to cover 92 for identification purposes.

Upon assembly of the components illustrated in the exploded view shown in FIG. 7, the upper part of case 61 will look like the illustration shown in FIG. 8. In particular, the pins of electrical conductor 64 will be generally coincident with indentation 80 to permit interconnection with other equipment/electrical connectors. The circuitry attendant the stacked PCBs is completely protected and secured in such a manner as to be unlikely to be affected by vibration within whatever environment the case may be employed.

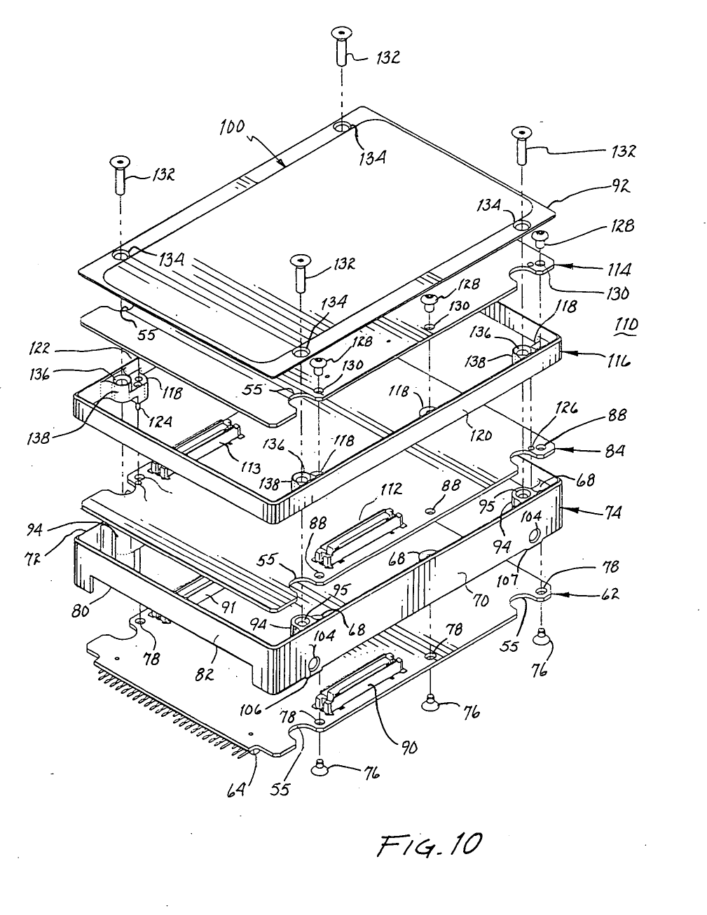

Case 61 may be attached to a support element by screws engaging the lower part of threaded passageway 95 in bosses 94. Spacer 74 includes further passageways 104 in sidewalls 70, 72 for use in attaching case 61 to a support element. Both of these modes of attachment are in accordance with the industry small form factor specification. Moreover, keys 106, 107 extend from sidewall 70 and similar keys, of which key 108 is shown in FIG. 9 and key 109 is shown in FIG. 16, extend from sidewall 72.

Referring jointly to FIGS. 10, 11 and 12, second variant 110 of a case 111 for stackable printed circuit boards (PCBs) will be described. As the second variant includes elements in addition to those described above with respect to first variant 60 (FIGS. 7, 8 and 9), common reference numerals will be used and the description of common elements will be relatively cursory. PCB 84 includes two or more electrical connectors 112, 113 extending upwardly therefrom. These electrical connectors mechanically and electrically interconnect with corresponding connectors dependingly supported from PCB 114 (see FIG. 16). A further spacer 116 includes supports 118 attached to or formed as part of the interior surface of sidewalls 120, 122 of the spacer. Downwardly extending pins 124 extend from supports 118 at opposed corners of spacer 116. These pins penetrably engage apertures 126 in PCB 84. Thus, upon assembly, pins 124, mating with apertures 126, positionally stabilize PCB 84 and spacers 74 and 116 and cause it to rest upon and bear against supports 68 formed as part of spacer 74. That is, the pins and corresponding apertures serve as registration elements to register spacers 74 and 116 with PCB 84, thus removing stress on mating electrical connections between the printed circuit boards. A plurality of screws 128 extend through apertures 130 in PCB 114 for threaded engagement with respective ones of supports 118 formed as part of spacer 116. Thereby, PCB 114 is secured to spacer 116. A flat cover 92 rests upon spacer 116. A plurality of elongated screws 132 extend through apertures 134 in cover 92. These screws slide through respective ones of passageways 136 in bosses 138 and into threaded engagement with the upper end of respective one of passageways 95 in bosses 94. A label 100 may be attached to cover 92 for identification purposes.

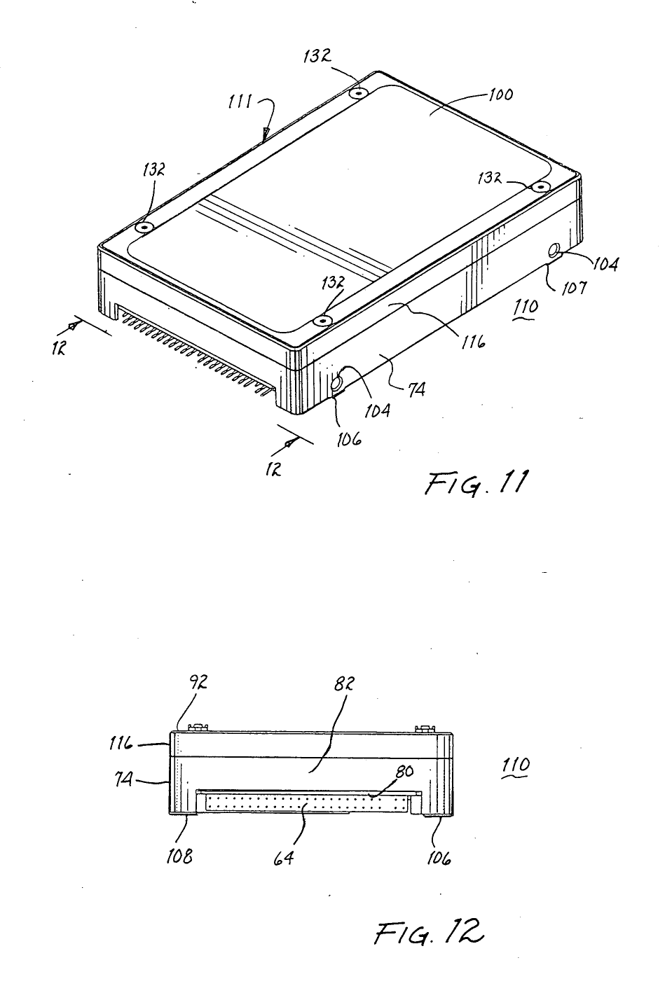

Upon assembly, as described with respect to FIG. 10, case 111 will look like the case illustrated in FIGS. 11 and 12. It will contain three stacked PCBs and access to the pins of electrical connector 64 will exist through indentation 80.

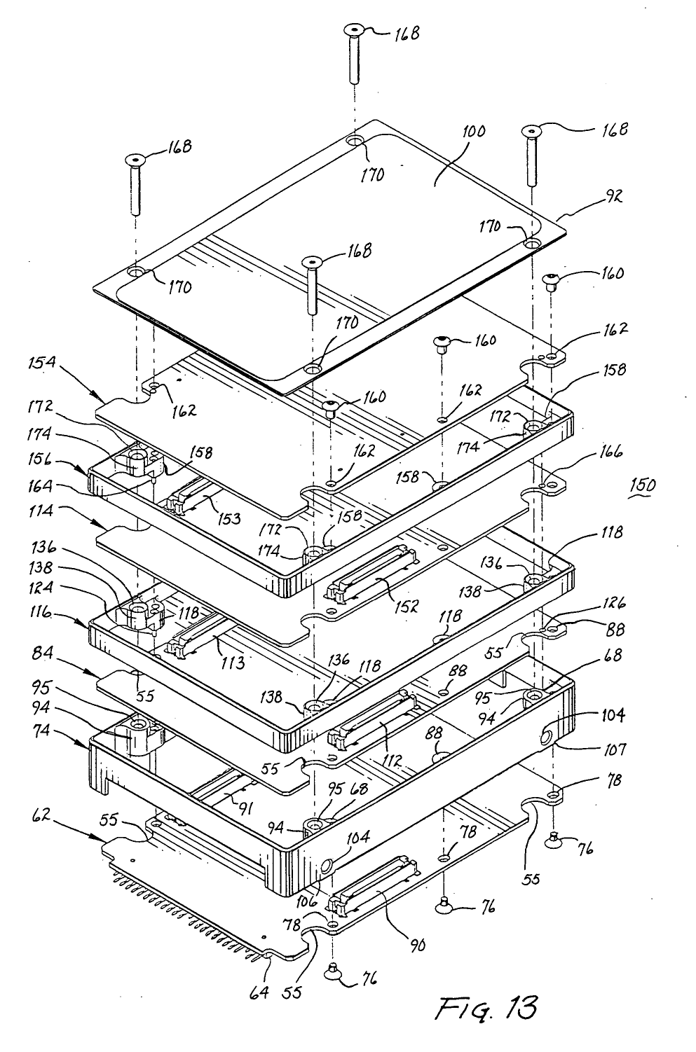

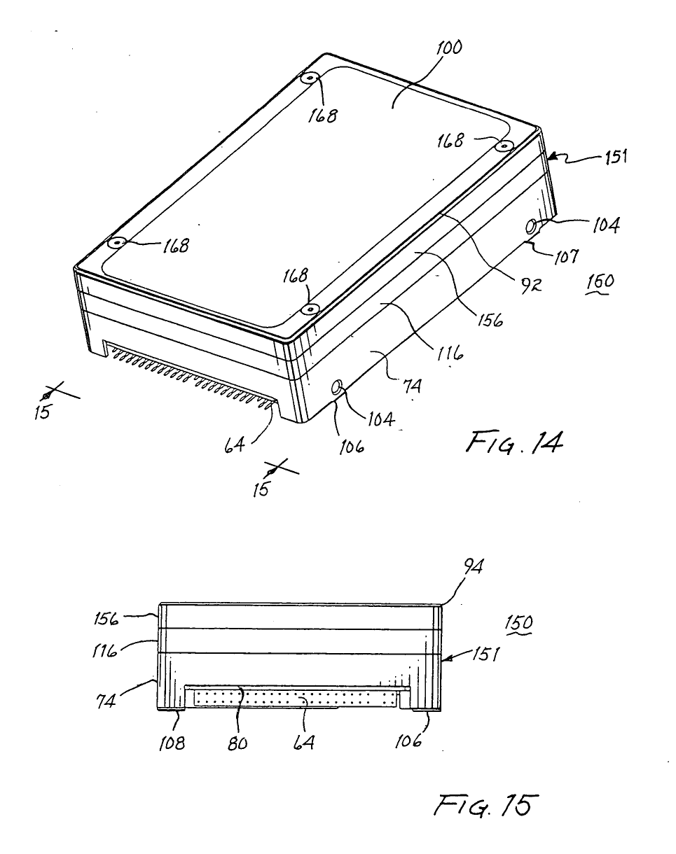

FIGS. 13, 14 and 15 illustrate a third variant 150 of a case 151 for stackable printed circuit boards. As significant similarity exists between the second and third variants illustrated in FIGS. 7, 8, 9, 10, 11 and 12, common reference numerals will be used and the description of common elements will be relatively cursory. PCB 114 includes electrical connectors 152, 153 for mechanically and electrically interconnecting corresponding electrical connectors depending from PCB 154 (see FIG. 16). A further spacer 156 includes supports 158 for supporting PCB 154 and this PCB is secured to the supports by screws 160 penetrating apertures 162 in the PCB and in threaded engagement with supports 158. Supports 158 at diagonally opposed corners of spacer 156 include a downwardly depending pin 164 for engagement with a corresponding aperture 166 in PCB 114. Thereby, PCB 114 is retained in place by these pins in the same manner as PCB 84 is retained in place by pins 124 extending from supports 118. That is, the pins and corresponding apertures serve as registration elements to register spacer 156 with PCB 114. Cover 92 is placed on the top of spacer 156 in juxtaposed relationship to PCB 154.

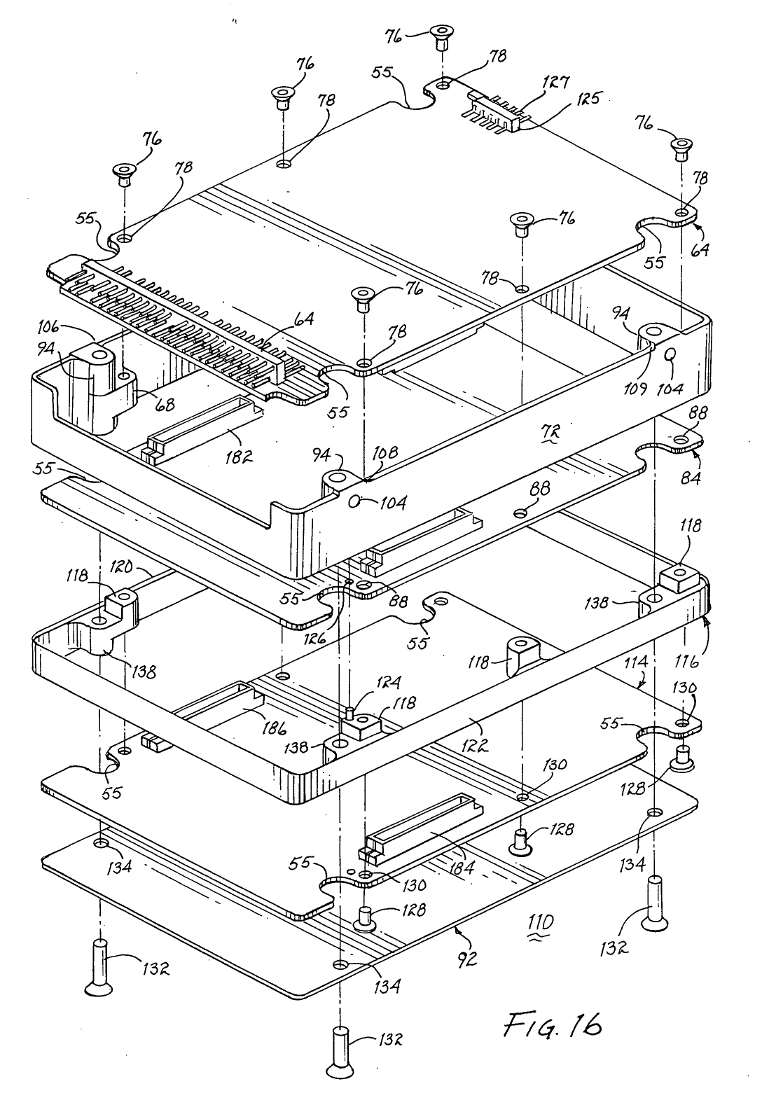

Cover 92 and spacers 74, 116 and 156 are secured to one another by elongated screws 168 extending through apertures 170 in cover 92, passageways 172 in bosses 174 formed as part of spacer 156, and into threaded engagement with the upper end of passageways 95 in bosses 94 formed as part of spacer 74. Upon such assembly, case 151 with internally stacked PCBs will look like the representation illustrated in FIGS. 14 and 15. By inspection, it will be evident that third variant 150 contains four electrically and mechanically interconnected PCBs 62, 84, 114 and 154 within a case 151 conforming with the industry small form factor specification. As shown in FIG. 14, a label 100 may be placed on top of cover 92 for identification purposes.

Referring to FIG. 16, there is shown a bottom view of second variant 110. Reference numerals common to the second variant illustrated in FIG. 10 will be used. The main purpose of FIG. 16 is that of illustrating the electrical connectors on the bottom of each of the PCBs (84, 114). Electrical connector 180 extending from the bottom of PCB 84 mechanically and electrically interconnects with electrical connector 91 mounted on the top of PCB 62. Similarly, electrical connector 182 on the bottom of PCB 84 mechanically and electrically interconnects with the other electrical connector 90 (see FIG. 10) extending upwardly from PCB 62. Electrical connector 184 extending downwardly from PCB 114 mechanically and electrically interconnects with electrical connector 113 on PCB 84 (see FIG. 10). Similarly, electrical connector 186 extending downwardly from PCB 114 mechanically and electrically interconnects with the other electrical connector 112 on PCB 84 (see FIG. 10). Thereby, the circuitry of PCB 62 is electrically connected with the circuitry of PCB 84 and the electrical circuitry of PCB 84 is electrically connected with the circuitry of PCB 114. FIG. 16 further illustrates the attachment of electrical connector 64 to the underside of PCB 62 as well as electrical connector 125 supporting pins 127 discussed above. It is to be understood that PCB 154 of third variant 150 (FIG. 13) would include similar electrical connectors on the underside to electrically and mechanically mate with electrical connectors 152, 153 on PCB 114.

Thereby, in addition to electrical interconnection provided between the stacked PCBs, the PCBs are also mechanically mated with one another via the various electrical connectors. While FIG. 16 primarily illustrates second variant 110, it is to be understood that the electrical connectors interconnecting adjacent stacked PCBs would be used in each of the variants forming the cases for stackable PCBs discussed as well as in any further variants which embody the present invention.

We claim:

1. A case adapted for housing electronic circuitry, said case comprising in combination:
a) a printed circuit board containing the electronic circuitry;
b) a cover for supporting said printed circuit board, said cover including sidewalls;
c) a plurality of supports extending from said sidewalls;
d) screw means for securing said printed circuit board to said plurality of supports; and
e) means for securing said case to a support element in accordance with the industry small form in accordance with the industry small form factor specification.

2. A case as set forth in claim 1, including an opening in said case and an electrical connector attached to said printed circuit board, said electrical connector being adapted for access through said opening.

3. A case as set forth in claim 2, a further opening in said case and a further electrical connector attached to said printed circuit board, said further electrical connector being adapted for access through said further opening.

4. A case as set forth in claim 1, said cover including a plurality of bosses having threaded apertures for receiving screws extending from the support element.

5. A case as set forth in claim 4 wherein each boss of said plurality of bosses is adjacent a support of said plurality of supports.

6. A case as set forth in claim 5 wherein each support of said plurality of supports includes a threaded aperture and wherein said screw securing means comprises a plurality of screws for threadedly engaging a respective threaded aperture of said plurality of supports.

7. A case as set forth in claim 6, including a plurality of holes disposed in said printed circuit board for penetrable engagement by a respective one of said screws.

8. A case as set forth in claim 4 wherein said printed circuit board includes a plurality of recesses, each of said recesses being coincident with one boss of said plurality of bosses.

9. A case for supporting a plurality of stacked electrically interconnected printed circuit boards, said case comprising in combination:
a) a spacer, said spacer including sidewalls having upper edges and lower edges;
b) a plurality of supports extending from at least an opposed pair of said sidewalls;
c) a plurality of bosses extending from at least an opposed pair of said sidewalls;
d) a first printed circuit board disposed generally coincident with said lower edges of said spacer;
e) a second printed circuit board disposed generally coincident with said upper edges of said spacer;
f) first attachment means for attaching said first printed circuit board to at least some of said supports;
g) second attachment means for attaching said second printed circuit board to at least some of said supports;
h) at least one electrical connector electrically interconnecting said first and second printed circuit boards;
i) an electrical connector attached to said first printed circuit board, said case including an opening to provide access to said electrical connector; and
j) a cover disposed adjacent said upper edges of said spacer.

10. A case as set forth in claim 9, including screws extending through said cover into threaded engagement with at least some of said plurality of bosses.

11. A case as set forth in claim 10 wherein each boss of said plurality of bosses includes a threaded passageway.

12. A case as set forth in claim 9 wherein said opening is defined by an indentation in one of said sidewalls of said spacer.

13. A case as set forth in claim 9 wherein said electrical connector attached to said first printed circuit board is disposed at the bottom of said first printed circuit board.

14. A case as set forth in claim 9 wherein said at least one electrical connector comprise a pair of electrical connectors.

15. A case as set forth in claim 14 wherein said pair of electrical connectors are disposed on facing sides of said first and second printed circuit boards.

16. A case as set forth in claim 9 including:
a) a further spacer, said further spacer including further sidewalls and having further upper edges and further lower edges;
b) a further plurality of supports extending from at least an opposed pair of said further sidewalls;
c) a further plurality of bosses extending from at least an opposed pair of said further sidewalls;
d) a third printed circuit board disposed generally coincident with said further upper edges of said further spacer;
e) third attachment means for attaching said third printed circuit board to at least some of said further plurality of supports;
f) at least a further electrical connector for electrically interconnecting said second and third printed circuit boards; and
g) wherein said screws extend through said cover, through at least some of said plurality of further bosses of said further spacer, and into threaded engagement with at least some of said plurality of bosses of said spacer.

17. A case as set forth in claim 16 wherein at least one of said further supports include a pin and wherein said second printed circuit board includes a hole for penetrable engagement with one of said pins.

18. A case as set forth in claim 16, including:
a) a yet further spacer, said yet further spacer including yet further sidewalls and having yet further upper edges and yet further lower edges;
b) a yet further plurality of supports extending from at least an opposed pair of said yet further side walls;
c) a yet further pair of bosses extending from at least an opposed pair of said yet further sidewalls;
d) a fourth printed circuit board disposed generally coincident with said yet further upper edges of said yet further spacer;
e) fourth attachment means for attaching said fourth printed circuit board to at least some of said yet further plurality of supports;
f) at least a yet further electrical connector electrically interconnecting said third and fourth printed circuit boards; and
g) wherein said screws extend through said cover, through at least some of said plurality of yet further bosses of said yet further spacer, through at least some of said plurality of further bosses of said further spacer and into threaded engagement with at least some of said plurality of bosses of said spacer.

19. A case as set forth in claim 18 wherein at least one of said yet further supports includes at least a pin and wherein said third printed circuit board includes at least a hole for penetrable engagement with one of said pins.

20. A case as set forth in claim 18 wherein said plurality of bosses are adapted to permit mounting said case to a support element in accordance with the industry small form factor specification.

21. A case for supporting a plurality of stacked electrically interconnected printed circuit boards, said case comprising in combination:
a) a spacer, said spacer including sidewalls having upper edges and lower edges;
b) a plurality of supports extending from at least one of said sidewalls;
c) a plurality of bosses extending from at least one of said sidewalls;
d) a first printed circuit board disposed generally coincident with said lower edges of spacer;
e) a second printed circuit board disposed generally coincident with said upper edges of said spacer;
f) first attachment means for attaching said first printed circuit board to at least some of said supports;
g) second attachment means for attaching said second printed circuit board to at least some of said supports;
h) at least one electrical connector electrically interconnecting said first and second printed circuit boards;
i) an electrical connector attached to one of said first and second printed circuit boards, said case including an opening to provide access to said electrical connector;
j) a cover disposed adjacent said upper edges of said spacer; and
k) screws extending through said cover and into threaded engagement with at least some of said plurality of bosses of said spacer.

22. A case as set forth in claim 21, including threaded apertures extending through each boss of said plurality of bosses and adapted for threaded engagement with a support element.

23. A case as set forth in claim 21 wherein said plurality of bosses includes two bosses disposed on opposed sidewalls of said spacer.

24. A case for housing a plurality of stacked printed circuit boards, said case comprising in combination:
a) at least one spacer;
b) at least one printed circuit board attached to said spacer;
c) an electrical interconnection between adjacent ones of said printed circuit boards present;
d) a cover; and
e) an electrical connector adapted for electrically connecting at least one of said first and second printed circuit boards with a further electrical connector located external to said case.

25. A case as set forth in claim 24, including a further spacer disposed intermediate said spacer and said cover for supporting a further printed circuit board and said electrical interconnection comprising a mating pair of electrical connectors between said further second printed circuit board and said at least one printed circuit board.

26. A case as set forth in claim 25, including a yet further spacer disposed intermediate said further spacer and said cover for supporting a yet further printed circuit board and said electrical interconnection comprising a mating pair of electrical connectors between said yet further printed circuit board and said further printed circuit board.

27. A case as set forth in claim 24, including threaded apertures formed as part of said spacer and adapted for threaded engagement with a supporting element.

28. A method for stacking printed circuit boards within a case having an externally accessible electrical connector, said method comprising the steps of:
a) mounting first and second printed circuit boards on a spacer;
b) electrically interconnecting one of the first and second printed circuit boards with the electrical connector;
c) further electrically interconnecting the first and second printed circuit boards with one another;
d) placing a cover on the spacer;
e) attaching the cover to the spacer; and
f) providing for support of the spacer on a support element.

29. A method as set forth in claim 28, including the steps of:
a) adding a further spacer intermediate the spacer and the cover;
b) further mounting a third printed circuit board on the further spacer, and
c) further electrically interconnecting the third printed circuit board with the second printed circuit board.

30. A method as set forth in claim 29, including the steps of:
a) further adding a yet further spacer intermediate the further spacer and the cover;
b) yet further mounting a fourth printed circuit board on the yet further spacer; and
c) yet further electrically interconnecting the fourth printed circuit board with the third printed circuit board.

31. A method as set forth in claim 28, including the step of exposing an electrical connector to an external mating electrical connector.

32. A method as set forth in claim 29, including the step of registering the further spacer with the second printed circuit board.

33. A method as set forth in claim 30, including the step of further registering the yet further spacer with the third printed circuit board.

34. A method as set forth in claim 33, including the step of registering the further spacer with the second printed circuit board.

35. A method for housing a printed circuit board within a case, said method comprising the steps of:
a) mounting a printed circuit board within a cover having sidewalls;
b) attaching the printed circuit board to supports extending from the cover;
c) exposing the underside of the printed circuit board;
d) providing access through an opening in the case to an electrical connector mounted on the printed circuit board; and
e) providing for attachment of the cover on a support element.

36. A method as set forth in claim 35 wherein said step of providing comprises the step of threadedly engaging screws extending from the support element with threaded apertures in bosses extending from sidewalls of the cover.

37. A method as set forth in claim 35 wherein said step of attaching includes the step of threadedly engaging screws extending through the printed circuit board with threaded passageways formed in the supports extending from sidewalls of the cover.

38. A method as set forth in claim 36 including the step of inserting the bosses within indentations in the printed circuit board upon exercise of said step of attaching.
